(19) United States
(12) Patent Application Publication
(10) Pub. No.: US 2026/0196440 A1
(43) Pub. Date: Jul. 9, 2026

(54) MAGNETICALLY ENHANCED RESISTIVE AND DIELECTRIC BARRIER DISCHARGE

(71) Applicant: Applied Materials, Inc., Santa Clara, CA (US)

(72) Inventors: Yogananda SARODE VISHWANATH, Bangalore (IN); John POULOSE, Sunnyvale, CA (US)

(21) Appl. No.: 18/938,137

(22) Filed: Nov. 5, 2024

(51) Int. Cl. H01J 37/32

(52) U.S. Cl. CPC H01J 37/321; H01J 37/32348; H01J 37/32568; H01J 37/32669; H01J 2237/332; H01J 2237/334

(57) ABSTRACT

The present disclosure provides a substrate processing chamber configured to produce an inductively coupled plasma. In one example, the substrate processing chamber includes a chamber body, a substrate support assembly disposed within the chamber body, a lid assembly enclosing a processing region within the chamber body, the lid assembly comprising an inductive coil configured to generate a plasma within the processing region of the chamber body, at least one magnet coupled to a magnet power source, and at least one electrode circumferentially extending along a perimeter of the chamber body. The at least one electrode is positioned below a metal lid support ring and above the at least one magnet.

### BACKGROUND

### Field

Embodiments of the present invention generally relate to systems and apparatuses of semiconductor manufacturing, and, more particularly, to systems and methods of generating a plasma for semiconductor substrate processing.

### Description of the Related Art

Inductively coupled plasma (ICP) process chambers are used in semiconductor manufacturing and generally form plasmas by inducing current in a process gas disposed within the process chamber via one or more inductive coils disposed outside of the process chamber. The inductive coils may be disposed externally and separated electrically from the chamber by, for example, a dielectric lid. When radio frequency (RF) current is fed to the inductive coils via an RF feed structure from an RF power supply, an inductively coupled plasma can be formed inside the chamber from an electric field generated by the inductive coils.

Under certain process conditions, ICP process chambers may produce non-uniformities in the electric field distribution of the plasma formed at the substrate level away from the coils. For example, due to etch rate non-uniformities caused by the non-uniform electric field distribution in the plasma, a substrate etched by such a plasma may result in a non-uniform etch pattern on the substrate, such as an M-shaped etch pattern, e.g., a center low and edge low etch surface with peaks between the center and edge.

Accordingly, there is a need for an improved plasma process apparatus to better control plasma processing non-uniformity.

### SUMMARY

The present disclosure provides a substrate processing chamber configured to produce an inductively coupled plasma. In one example, the substrate processing chamber has a chamber body, a substrate support assembly disposed within the chamber body, a lid assembly enclosing a processing region within the chamber body, the lid assembly comprising an inductive coil configured to generate a plasma within the processing region of the chamber body, at least one magnet coupled to a magnet power source, and a plurality of electrodes positioned in a radial pattern within a metal ring, wherein the plurality of electrodes are placed above the at least one magnet.

In another example, the substrate processing chamber has a chamber body, a substrate support assembly disposed within the chamber body, a lid assembly enclosing a processing region within the chamber body, the lid assembly comprising an inductive coil configured to generate a plasma within the processing region of the chamber body, at least one magnet coupled to a magnet power source, and a single electrode positioned within a metal ring to circumferentially extend along a perimeter of the chamber body, wherein the single electrode is placed above the at least one magnet.

In another example, a method includes forming a substrate support assembly within a chamber body, disposing a lid assembly enclosing a processing region within the chamber body, the lid assembly comprising an inductive coil configured to generate a plasma within the processing region of the chamber body, placing at least one magnet adjacent the chamber body, and positioning at least one electrode within a metal ring to circumferentially extend along a perimeter of the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 is a schematic cross-sectional view of a substrate processing system having a plasma confinement system, according to one or more embodiments.

FIG. 2 is a schematic top view of the substrate processing chamber illustrating segmented electrodes adjacent a metal lid support ring for supporting magnetically enhanced resistive barrier discharge, according to one or more embodiments.

FIG. 3 is a schematic top view of the substrate processing chamber illustrating a single electrode adjacent a metal lid support ring for supporting magnetically enhanced dielectric barrier discharge, according to one or more embodiments.

FIG. 4 is a schematic, cross-sectional view of the substrate processing chamber illustrating the electrode integrated within the metal ring, according to one or more embodiments.

FIG. 5 illustrates a schematic, cross-sectional view of a substrate processing chamber showing the electrode integrated within the metal ring, according to certain embodiments.

FIG. 6 is a flowchart of using segmented electrodes adjacent a metal lid support ring for supporting magnetically enhanced resistive barrier discharge, according to certain embodiments.

FIG. 7 is a flowchart of using a single electrode adjacent a metal lid support ring for supporting magnetically enhanced dielectric barrier discharge, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to systems and apparatuses of semiconductor manufacturing, and, more particularly, to systems and methods of generating a plasma for semiconductor substrate processing.

An inductively coupled plasma (ICP) is generated in a substrate processing chamber by supplying energy through electric currents produced by electromagnetic induction, i.e., by time-varying magnetic fields. An induction coil forms a strong magnetic field inside the chamber. When a time-varying electric current is passed through the coil, a time-varying magnetic field is created. This magnetic field induces an azimuthal electromotive force in a process gas, leading to the formation of electron trajectories and thus generating plasma. The ICP torch consumes about 1250-1550 W of power, but this depends on the elemental composition of the sample due to different ionization energies. Improving the etch rate of generated plasma is often desirable. A faster etch rate can increase the efficiency of the etching process, reducing the time it takes to remove material from the surface of a substrate. This is particularly beneficial for applications with deep features. Improving the etch rate can also enhance the uniformity of the etching across the substrate.

Semiconductor devices can be generated by forming one or more films on a substrate. The formed films can include silicon-, nitride-, and oxide-containing films, among others. Processing chambers for processing substrates can be configured to perform etching or chemical vapor deposition (CVD) including plasma-enhanced CVD (PECVD), plasma-enhanced atomic layer deposition (PEALD), or physical vapor deposition (PVD), among other plasma processes. The quality of the films etched on the substrates can be impacted negatively due to the difference, or non-uniformity, of the plasma density or the amount of plasma scatter over a substrate within the processing chamber. The difference in the plasma density within the processing volume of the processing chamber may negatively affect the edge-to-edge uniformity of the films formed on a substrate. Any non-uniformity of the films may result in a drop in production yield, increasing the manufacturing costs of semiconductor devices. Furthermore, the plasma scatter results in excess energy consumption driving up the cost of substrate processing within the processing chamber.

The plasma confinement system and method discussed herein functions to improve the uniformity of plasma density within the processing volume, and in particular, plasma scatter may be reduced significantly. In one example, segmented electrodes are placed within a metal ring and resistive barrier discharge (RBD) takes place to create a high voltage near a chamber lid of a processing chamber, near the inductive coils (or ICP coils), such that the voltage stacks on to the ICP's to assist with plasma breakdown. In another example, a single electrode is placed within a metal ring and dielectric barrier discharge (DBD) takes place to create a high voltage near a chamber lid of a processing chamber, near the inductive coils (or ICP coils), such that the voltage stacks on to the ICP's to assist with plasma breakdown.

Plasma breakdown occurs when the electric field applied to a gas surpasses a threshold. The field accelerates free electrons, which collide with neutral atoms or molecules. If the energy of these collisions exceeds the ionization potential of the gas atoms or molecules, they will eject electrons and become positively charged ions. These newly freed electrons also accelerate and collide with other neutral gas molecules, triggering a chain reaction of ionization, leading to plasma formation. Breakdown voltage is the minimum voltage needed to initiate plasma breakdown. This voltage depends on factors like gas type, pressure, electrode configuration, and the distance between electrodes. In plasma processing chambers, breakdown occurs in the range of a few hundred to several thousand volts, depending on the system design and operating pressure. Controlling the plasma breakdown process is beneficial for optimizing material etching, deposition, or surface treatment. Proper plasma initiation ensures that the gas is ionized uniformly, providing consistent energy and particle flux to the target material. Too high of a breakdown voltage can result in arcing, which damages the material or equipment, while too low of a voltage may lead to incomplete ionization or non-uniform plasma. Thus, breaking down plasma can help achieve uniform plasma distribution across the surface of the material being processed. This results in consistent material characteristics, which is valuable for producing high-quality semiconductor devices or thin films. The example embodiments break down plasma by incorporating either segmented electrodes or a single electrode in a metal ring of the processing chamber to create a high voltage near the chamber lid and near the ICP coils, using either RBD or DBD. The combined effect of the electrodes and magnets leads to more efficient use of the plasma across the entire processing area, ensuring high yield. The combination of a metal lid support ring, a dielectric material, the electrodes, and the magnets ensures confinement of the plasma within a desired area and ensures that the plasma remains evenly distributed across the substrate. By controlling both the electric and magnetic fields, the system achieves consistent plasma characteristics, improving process outcomes.

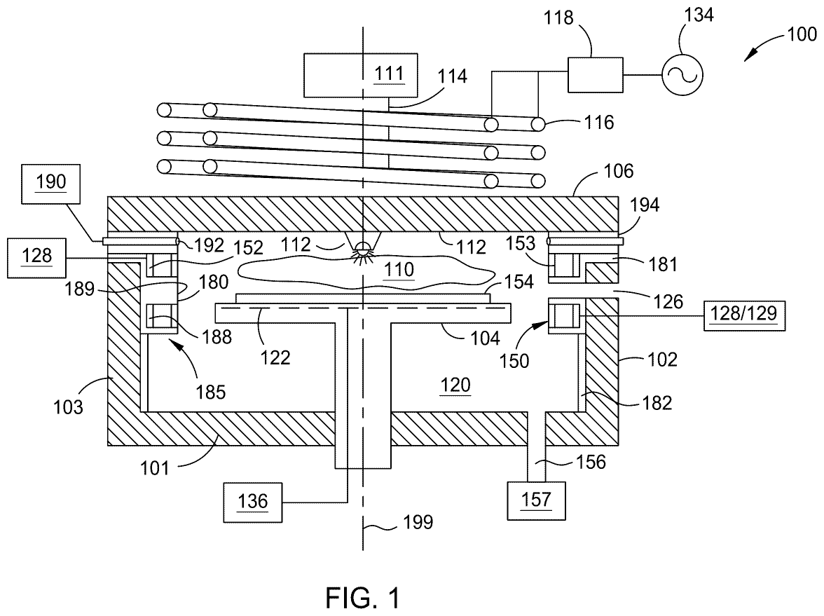

FIG. 1 illustrates a schematic cross-sectional view of a processing chamber 100 having a plasma confinement system 185, according to one implementation described herein. The processing chamber 100 is illustrated as a etch chamber, but the processing chamber 100 may alternatively be another type of plasma enhanced processing chamber. The processing chamber 100 includes a chamber body 102 and a lid 106 disposed on the chamber body 102. The chamber body 102 may include a bottom chamber wall 101 and a chamber sidewall 103. The bottom chamber wall 101, the chamber sidewall 103 and the lid 106 enclose a processing volume 120. A centerline 199 of the processing chamber 100 is equidistant from the chamber sidewall 103 and disposed through the center of the bottom chamber wall 101 and lid 106. While the plasma confinement system 185 of FIG. 1 is illustrated for use in a etch chamber, the plasma confinement system 185 of FIG. 1 may be used with other processing chambers that utilize plasma generated in the processing volume 120.

A substrate support 104 is disposed inside the processing volume 120. The substrate support 104 is centered about the centerline 199. The substrate support 104 is configured to support a substrate 154 thereon during processing. The substrate 154 is transferred into and out of the processing volume 120 through a slit opening 126 formed through the chamber sidewall 103.

The lid 106 includes an injection apparatus 112. The injection apparatus 112 fluidly couples a gas supply source 111 to the processing volume 120. The injection apparatus 112 is coupled via a conduit 114 to the gas supply source 111. The gas supply source 111 supplies process gas through the conduit 114 to the injection apparatus 112. The injection apparatus 112 may be one or more nozzle or inlet ports, or alternatively a showerhead. The nozzle, i.e., injection apparatus 112, has a plurality of openings through which the gas flows out the nozzle into the processing volume 120. In the etch chamber configuration depicted in FIG. 1, the injection apparatus 112 is a nozzle. In other chamber configurations such as a CVD deposition chamber, the injection apparatus 112 may be a showerhead.

The processing gas may be energized to form plasma 110 within the processing volume 120. The processing gas may be energized by capacitively or inductively coupling radiofrequency (RF) power to the processing gases. In the embodiment depicted in FIG. 1, a plurality of coils or inductive coils 116 are disposed above the lid 106 of the processing chamber 100 and coupled through a matching circuit 118 to an RF power source 134 for inductively coupling the RF power to the processing gas. The RF power source 134 is configured to energize the gas in the processing volume 120 for forming and maintaining the plasma 110.

The gas supply source 111 may include one or more gas sources. The gas supply source 111 is configured to deliver the one or more gases from the one or more gas sources through the injection apparatus 112 to the processing volume 120. Each of the one or more gas sources provides a processing gas (such as argon, hydrogen or helium) that may be ionized to for plasma formation. For example, one or more of a carrier gas and an ionizable gas may be provided into the processing volume 120 along with one or more precursors. When processing the substrate 154, the processing gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be coupled to the gas supply source 111 and be used to deliver reactive species into the processing chamber 100.

An exhaust port 156 is coupled to a vacuum pump 157 and is disposed along the wall of the processing chamber 100. The vacuum pump 157 removes excess process gases or by-products from the processing volume 120 during and/or after processing via the exhaust port 156.

The substrate support 104 contains or is formed from a metal or ceramic material. Exemplary ceramic materials include one or more metals, metal oxides, metal nitrides, metal oxynitrides, or any combination thereof. For example, the substrate support 104 may be formed from a metal aluminum or a ceramic such as aluminum oxide, aluminum nitride, aluminum oxynitride, or any combination thereof.

An electrode 122 is embedded within the substrate support 104, but may alternatively be coupled to a surface of the substrate support 104. The electrode 122 is coupled to a power source 136. The power source 136 is configured to provide DC power, pulsed DC power, radio frequency (RF) power, pulsed RF power, or any combination thereof to the electrode 122. The power source 136 drives the electrode 122 with a drive signal that energizes the plasma within the processing volume 120. The drive signal may be one of a DC signal and a varying voltage signal (e.g., RF signal).

The plasma 110 is maintained in the processing volume 120 via inductive coupling to the RF power supplied by the RF power source 134. An RF field is created by driving at least one of the top electrode, i.e., the inductive coils 116, and the electrode 122 with drive signals to facilitate the formation of a capacitive plasma within the processing volume 120. The presence of a plasma facilitates processing of the substrate 154, for example, etching of a film on a surface of the substrate 154.

A top liner 194 is disposed adjacent to the chamber body 102 and separates the chamber body 102 from the lid 106. In one example, a bottom surface of the top liner 194 rests on the chamber body 102. The top liner 194 may be part of the lid 106, but may alternately be separate from the lid 106. The top liner 194 may be an annular, or ring-like member, and may include one or more side gas feed nozzles 192. The side gas feed nozzle 192 is coupled to a side gas supply 190. In one example, the top liner 194 has eight side gas feed nozzles 192. The side gas feed nozzles 192 may be oriented to inject a gas parallel to the injection apparatus 112. Alternately, the side gas feed nozzles 192 may be angled downward away from the injection apparatus 112 to inject a gas inward toward the centerline 199 and away to the injection apparatus 112. In this manner, gas flowing through the side gas feed nozzles 192 is directed inward at the plasma 110. In one example, the side gas feed nozzles 192 helps confine the plasma 110 about the centerline 199 in the processing volume 120 and above the substrate support 104. The angle of the side gas feed nozzles 192 pointing towards the substrate 154 assists in densifying the plasma 110 and improving process uniformity.

The plasma confinement system 185 includes a chamber wall liner 180 and a plasma confinement assembly 150. The plasma confinement system 185 may additionally include the one or more side gas feed nozzles 192 discussed above. The chamber wall liner 180 is particularly configured for use with the plasma confinement assembly 150. That is, the chamber wall liner 180 may be provided with the plasma confinement assembly 150.

The chamber wall liner 180 is ring shaped and may be disposed on the chamber sidewall 103 in the chamber body 102. The chamber wall liner 180 has an inner wall 189. The inner wall 189 being the innermost wall of the chamber wall liner 180 and facing the processing volume 120 of the processing chamber 100. The chamber wall liner 180 is disposed between the chamber sidewall 103 and the processing volume 120. The slit opening 126 extends through the chamber wall liner 180 and the inner wall 189 to provide access to the processing volume 120. The chamber wall liner 180 is replaceable and is made from a material configured to protect the chamber sidewall 103 from the plasma 110. The chamber wall liner 180 may also be grounded to a common ground of the processing chamber 100.

The chamber wall liner 180 has one or more confinement cavities 188 therein. The one or more confinement cavities 188 extend through the inner wall 189 of the chamber wall liner 180. The confinement cavities 188 are sized and configured for the plasma confinement assembly 150 to be disposed therein. The plasma confinement assembly 150 alters the density of the plasma 110 and shapes and/or moves the plasma 110 with respect to the chamber wall liner 180 and substrate support 104.

The chamber wall liner 180 may optionally extend between the chamber body 102 and the top liner 194. The chamber wall liner 180 includes an upper wall liner 181 and a lower wall liner 182. The upper wall liner 181 may extend above the slit opening 126. The lower wall liner 182 extends from the upper wall liner 181 to the bottom 101 of the chamber body 102. In one example, the upper wall liner 181 and lower wall liner 182 are monolithic, i.e., of a single solid piece of material.

The lower wall liner 182 is ring shaped and may generally be formed from a ceramic material. In one embodiment, the lower wall liner 182 is formed from AlN, Al₂O₃ or other suitable materials. The lower wall liner 182 may be coated, for example, with yttria or other material. The lower wall liner 182 may be of a substantially consistent thickness. In one example, the lower wall liner 182 may be part of the upper wall liner 181 as a single piece chamber wall liner 180. In another example, the lower wall liner 182 may be separate from the upper wall liner 181 forming a two piece chamber wall liner 180.

The plasma confinement assembly 150 disposed in the first cavity has a magnet 152 and an optical window 153. The magnet 152 may be an electromagnet coupled to a first power source 128. The optical window 153 shields the magnet 152 from the processing chamber environment while allowing a magnetic field of the magnet 152 to penetrate through the optical window 153 into the processing volume 120. The optical window 153 may be quartz or other suitable material. Another magnet may be coupled to a second power source 129.

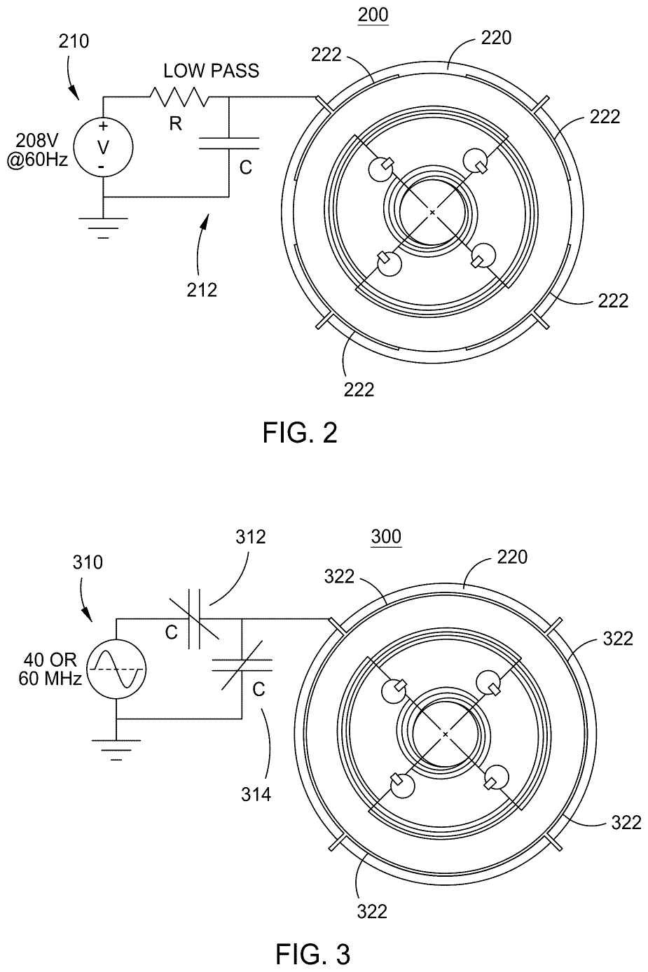

FIG. 2 is a schematic top view of the substrate processing chamber illustrating segmented electrodes adjacent a metal lid support ring for supporting magnetically enhanced resistive barrier discharge, according to one or more embodiments.

In the top view 200, the electrodes 222 are shown. The electrodes 222 may be referred to as segmented electrodes or discontinuous electrodes. The electrodes 222 are equally spaced apart from each other. In one example, there are four electrodes. Of course, any other number of equally spaced apart electrodes may be contemplated extending circumferentially around the chamber body 102. The electrodes 222 may be placed adjacent a metal lid support ring 220. The metal lid support ring 220 helps maintain the alignment and positioning of the lid 106 to maintain the vacuum environment and ensure proper chamber function. The electrodes 222 may be powered by a power supply 210. The power supply 210 may be coupled to a low pass filter (LPF) 212 including a resistor and a capacitor.

The electrodes 222 are positioned in a radial pattern below the metal lid support ring 220 to distribute high voltage across specific points within the processing chamber 100. The radial configuration helps to generate a more even electric field around the perimeter of the processing chamber 100. Applying high voltage to these radial points increases the strength of the electric field in localized areas, assisting in the breakdown of the process gas into the plasma 110. The positioning of the electrodes 222 helps to lower the breakdown voltage needed to initiate the plasma. By concentrating the electric field at specific points, the plasma breakdown process becomes more efficient, reducing the energy needed to sustain the plasma 110.

Low pass filters (LPFs) 212 are used to block or attenuate high-frequency components in signals. When coupled with the inductive coils 116 in the processing chamber 100, the LPF 212 out high-frequency noise generated by the power supply 210 or external electromagnetic sources. This helps stabilize the operation of the inductive coils 116, which are used to generate electromagnetic fields or drive plasma in the processing chamber 100. The use of LPFs 212 improves stability in plasma generation and reduces noise interference, leading to more uniform and controlled processing of the substrate 154.

The inductive coils 116 in the processing chamber 100 are driven by RF or alternating current (AC) power supplies. LPFs 212 ensure that only the desired low-frequency component of the power reaches the inductive coils 116. By smoothing out the power delivered to the inductive coils 116, the LPF 212 prevents fluctuations and transient spikes, which can otherwise cause instability in the electromagnetic field or plasma generation. This results in more consistent power delivery, which leads to stable chamber conditions, and improved uniformity and quality of processes like etching, deposition, or cleaning.

Stated differently, harmonics are unwanted high-frequency components that can arise in RF power systems. In RF plasma systems where the inductive coils 116 are used, harmonics can affect the efficiency of power transfer and cause fluctuations in the plasma density. The LPF 212 eliminates these harmonics, ensuring that only the fundamental frequency is delivered to the inductive coils 116. This leads to more efficient power usage, more controlled plasma characteristics, and better process repeatability.

Further, the inductive coils 116 are used to create the plasma 110 in processes like etching or thin-film deposition. The LPF 212 ensures that the power delivered to the inductive coils 116 is smooth and consistent, reducing fluctuations that can lead to non-uniform plasma. This improves the uniformity of plasma distribution across the substrate 154, leading to higher-quality manufacturing with fewer defects or variations.

As such, coupling the LPF 212 with the inductive coils 116 in the processing chamber 100 can stabilize the power supply 210, reduce unwanted high-frequency noise and harmonics, and improve plasma uniformity.

The power supply 210 powers the electrodes 222. By incorporating segmented electrodes into the processing chamber 100, resistive barrier discharge principles can be applied to enhance plasma initiation, breakdown, and stability, particularly near the inductive coils 116 and the lid 106. Resistive barrier discharge (RBD) is a type of electrical discharge that occurs in a gas when a resistive element is placed between electrodes and a dielectric barrier, creating conditions for plasma generation. It is a variation of dielectric barrier discharge (DBD), but with an additional resistive layer that controls the current flow, preventing electrical arcing and allowing for more controlled, uniform micro-discharges.

Stated differently, in RBD, a resistive material (such as a high-resistance coating or resistive electrode) is added between the high-voltage power source and the dielectric barrier. This resistive layer limits the current, ensuring the discharge remains non-thermal and is made up of micro-discharges rather than a continuous arc. The discharge occurs in the form of many small, localized micro-discharges across the surface of the dielectric. These micro-discharges are spatially and temporally confined, ensuring a uniform plasma distribution. RBD generates non-thermal plasma, where the electrons are much hotter than the neutral gas. This allows chemical reactions to occur without significantly heating the substrate or surrounding materials.

The advantages of RBD include the resistive element helping ensure that the plasma 110 is generated more evenly over the surface, reducing the risk of hot spots or arcing. By limiting current flow, RBD provides more precise control over the plasma 110. The resistive barrier helps prevent arcing, which can cause damage to materials and reduce the efficiency of the process.

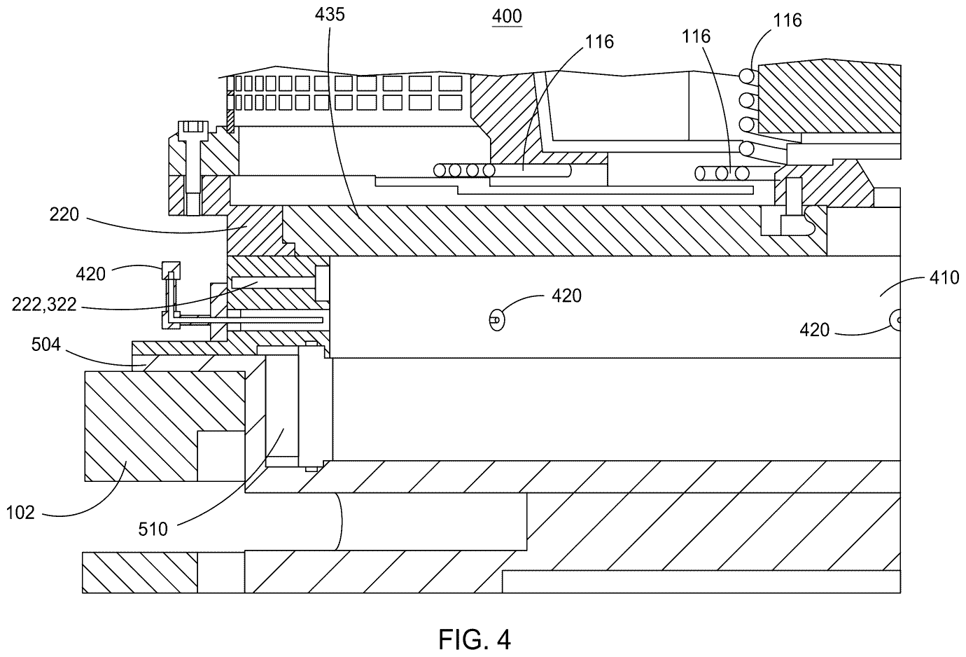

Creating a RBD system using the electrodes 222 integrated into a metal ring can enhance plasma breakdown near critical areas like the lid 106 or the inductive coils 116. The electrodes 222 are spaced evenly around the circumference of the metal lid support ring 220. The high electric field generated by the electrodes 222 will help ignite the plasma 110 by accelerating electrons and ions in the gas phase. The dielectric material 435 (FIG. 4) ensures micro-discharges occur, preventing arcing or thermal damage to chamber components. The segmented electrodes 222 provide a uniform electric field distribution, preventing the plasma 110 from collapsing or becoming unstable near the lid 106 or the inductive coils 116 to ensure that plasma density is maintained throughout the process.

Therefore, having RBD would create a high voltage near the lid 106, near the primary ICP coil, and that voltage will stack on to the inductive coils 116 and help with plasma breakdown. Plasma breakdown in plasma processing chambers refers to the point at which a neutral gas becomes ionized and transforms into a plasma. Plasma breakdown occurs when an external energy source, such as an electric field, induces enough energy into the gas to strip electrons from atoms or molecules, creating a mix of free electrons, ions, and neutral particles. This state enables the plasma to conduct electricity and interact with surfaces, making it a valuable mechanism in various semiconductor and materials processing applications, including etching, deposition, and cleaning. The RBD in combination with the electrodes 222 assists in generating high-density plasma and ensuring uniform and stable plasma breakdown.

FIG. 3 is a schematic top view of the substrate processing chamber illustrating a single electrode adjacent a metal lid support ring for supporting magnetically enhanced dielectric barrier discharge, according to one or more embodiments.

In the top view 300, the single electrode 322 is shown. The single electrode 322 may be referred to as a continuous or non-interrupted electrode. The single electrode 322 may be placed adjacent the metal lid support ring 220. The single electrode 322 may be powered by a power supply 310. The power supply 310 may be coupled to a first variable capacitor 312 and a second variable capacitor 314. The power supply may be an AC voltage source. An AC voltage source with two variable capacitors powering inductive coils 116 in the processing chamber 100 serve to control and optimize plasma generation, electromagnetic field uniformity, and energy transfer.

The first variable capacitor 312 and the second variable capacitor 314 allow precise tuning of the resonant frequency of an inductor-capacitor (LC) circuit (not shown). By adjusting the capacitance values, the circuit can be tuned to resonate at the desired frequency of the AC voltage source. This ensures that the inductive coils 116 generate the maximum electromagnetic field strength, efficiently ionizing the gas in the processing chamber 100 and creating a stable plasma. Optimal plasma generation with more control over its characteristics (density, uniformity) improves substrate processing (e.g., etching, deposition).

In the processing chamber 100, it is beneficial to control the characteristics of the plasma 110 (such as density, ionization rate, and temperature) to achieve desired process outcomes. By varying the capacitance values of the first variable capacitor 312 and the second variable capacitor 314, the LC circuit can control the frequency and power delivered to the inductive coils 116. This, in turn, adjusts the electromagnetic field generated by the inductive coils 116, influencing the behavior of the plasma 110 (e.g., controlling the energy of the electrons and ions in the plasma). Fine-tuning the first and second variable capacitors 312, 314 allows for precise control over the plasma's temperature and density. More precise control over the plasma process improves the uniformity of the substrate treatment and reduces defects.

Moreover, the first and second variable capacitors 312, 314 can be used to fine-tune the AC power delivery to the inductive coils 116, stabilizing the plasma discharge by ensuring the electromagnetic field remains consistent and balanced. This stabilization reduces the likelihood of arcing or hot spots in the plasma, leading to a more uniform and controlled plasma field. The discharge can be a dielectric barrier discharge (DBD). DBD is a type of plasma discharge that occurs between two electrodes, at least one of which is covered by a dielectric (insulating) material. The dielectric barrier limits the current and prevents a continuous arc discharge, allowing the system to generate non-thermal plasma (e.g., cold plasma). When high-voltage power is applied, the gas between the electrodes becomes ionized, creating a plasma. The dielectric barrier prevents the current from forming a continuous arc by limiting the charge transfer, resulting in non-thermal plasma consisting of micro-discharges.

The defining characteristic of DBD is the presence of a dielectric material (e.g., glass, quartz, or ceramics) placed between the electrodes. This barrier regulates the discharge by limiting the charge buildup, preventing thermal breakdown and arcing. When the voltage across the electrodes reaches a critical level, small, localized plasma filaments, or micro-discharges, occur. These micro-discharges are short-lived (nanoseconds to microseconds) and distributed over the surface of the dielectric. DBD generates non-thermal plasma, meaning the electron temperature is much higher than the temperature of the neutral gas. This allows energetic chemical reactions without significantly heating the overall system. The advantages of DBD include that the dielectric barrier prevents the formation of a continuous arc, ensuring the discharge remains in a controlled, non-thermal state.

Creating a DBD system using the single electrode 322 integrated into a metal ring can enhance plasma breakdown near critical areas like the lid 106 or the inductive coils 116. The high electric field generated by the single electrode 322 will help ignite the plasma 110 by accelerating electrons and ions in the gas phase. The dielectric material 435 (FIG. 4) ensures micro-discharges occur, preventing arcing or thermal damage to chamber components. The single electrode 322 provides a uniform electric field distribution, preventing the plasma 110 from collapsing or becoming unstable near the lid 106 or the inductive coils 116. This is useful in ensuring that plasma density is maintained throughout the process.

Therefore, having DBD would create a high voltage near the lid 106, near the primary ICP coil, and that voltage will stack on to the inductive coils 116 and help with plasma breakdown. The DBD in combination with the single electrode 322 assists in generating high-density plasma and ensuring uniform and stable plasma breakdown.

Moreover, magnetic confinement below the single electrode 322 may limit the ion flux to the chamber walls, thereby preventing erosion. Direct ion flux to the single electrode 322 can cause physical erosion over time, especially during high-energy processes like etching. The magnetic field below the single electrode 322 confines ions away from the electrode surface, thus reducing ion bombardment and minimizing wear. Reducing ion bombardment on the single electrode 322 decreases the rate of erosion, extending the lifetime of such components and reducing downtime and maintenance. Also, erosion of the electrode material can introduce contaminants into the plasma 110, which may deposit on the substrate 154, leading to defects in the final product. Magnetic confinement may reduce this risk.

Also, in one example, the magnetic coil and the ICP coil have current flowing in the same orientation such that the magnetic fields generated by both coils interact, potentially leading to reinforcing or modifying the overall magnetic confinement and plasma characteristics. The magnetic coil generates a low-frequency magnetic field used to confine the charged particles within the plasma. The ICP coil generates a high-frequency oscillating magnetic field by inducing an electric current in the gas inside the processing chamber 100. When the current flows in the same direction in both the magnetic coil and the ICP coil, their magnetic fields can align and reinforce each other to enhance plasma confinement. With better electron confinement, fewer electrons are lost to chamber walls, and, as a result, the plasma 110 can be sustained more efficiently. The ion flux toward the chamber components is also better controlled, helping to prevent erosion and extend component life.

FIG. 4 is a schematic, cross-sectional view of the substrate processing chamber illustrating the electrode integrated within the metal ring, according to one or more embodiments.

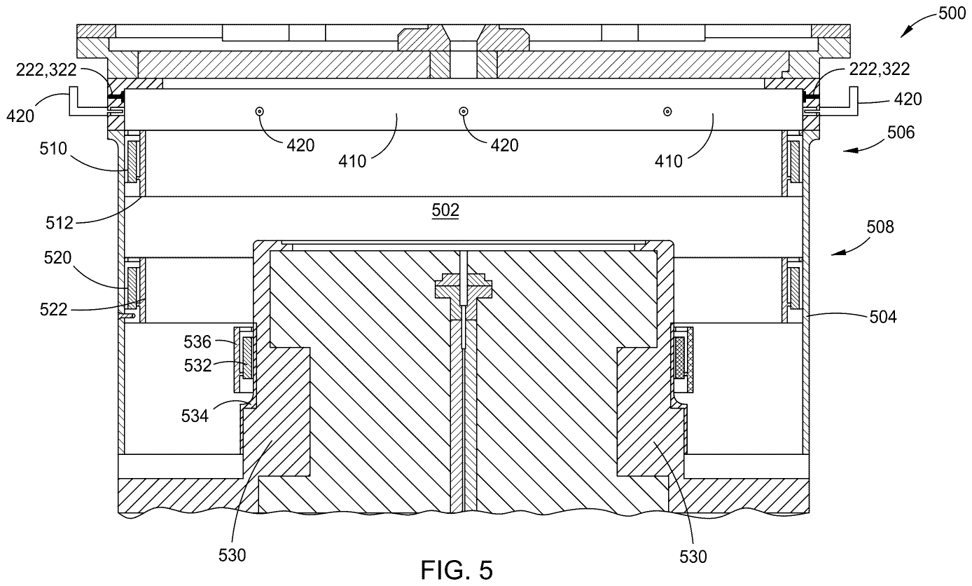

The cross-sectional view 400 depicts the electrode (e.g., the segmented electrodes 222 or the single electrode 322) integrated with the metal ring 410. The metal ring 410 may include a plurality of gas nozzles 420. The gas nozzles 420 are used to introduce and distribute various gases into the processing chamber 100. The gas nozzles 420 ensure gases are evenly distributed across the substrate 154 to maintain consistency in the process, such as etching and deposition. The electrode or electrodes may be placed above the upper magnet 510 and the lower magnet 520 (FIG. 5). The electrode or electrodes may be placed above the chamber liner 504 which cooperates with the chamber body 102. The electrode or electrodes may be placed below the metal lid support ring 220 and a dielectric material 435. The metal lid support ring 220 provides structural support for the dielectric material 435 and ensures that the processing chamber 100 remains sealed. The metal lid support ring 220 further ensures that that the lid 106 remains stable. Since plasma generation involves RF energy, the metal lid support ring 220 helps conduct electrical energy to maintain the electric field necessary for plasma breakdown. The dielectric material 435 can also influence how the plasma 110 forms and how it interacts with the substrate 154. The dielectric material 435 further insulates certain parts within the processing chamber 100 to prevent unwanted arcing or electrical discharge.

The upper magnet 510 is placed below the electrodes (222, 322) and the dielectric material 435 to shape and confine the plasma 110, helping prevent the plasma 110 from diffusing away from the region where processing is taking place. The electrode or electrodes (222, 322) are placed below the dielectric material 435 and the upper magnet 510 to create the electric field necessary to ignite the plasma 110. The power applied to the electrode or electrodes (222, 322) excites the gas molecules, causing ionization and breakdown of the plasma 110. As such, the electrodes (222, 322) create an electric field, the magnets create a magnetic field, the electric and magnetic fields interacting with each other to confine and control the movement of electrons within the plasma 110. The combination of the metal lid support ring 220, the dielectric material 435, the electrodes (222, 322), and the magnets (510, 520) ensure confinement of the plasma 110 within a desired area and ensure that the plasma 110 remains evenly distributed across the substrate 154. By controlling both the electric and magnetic fields, the system achieves consistent plasma characteristics, improving process outcomes.

Incorporating segmented electrodes or a single electrode near the chamber lid and near ICP coils to assist with plasma breakdown in a processing chamber offers several advantages, particularly in enhancing plasma generation, uniformity, and control. These benefits are especially beneficial in processes like plasma etching or deposition, where precise control over plasma characteristics is necessary for optimizing production throughput and product quality. By placing electrodes near the chamber lid and ICP coils, localized high-voltage zones can be created, which help initiate plasma breakdown more easily by enhancing the electric field in the chamber. This allows for plasma to form at a lower breakdown voltage, reducing the overall power requirements of the system.

Lowering the breakdown voltage can also extend the lifespan of power delivery components and reduce the risk of electrical damage to chamber components. Adding electrodes can help to distribute the electric field more evenly within the processing chamber, improving the uniformity of the plasma. Uniform plasma is beneficial for achieving consistent material processing, as uneven plasma can lead to non-uniform etching or deposition, potentially causing defects in substrates. This uniformity is useful in large-area processing, where maintaining consistent plasma characteristics across the entire substrate is a challenge. The placement of electrodes near the ICP coils can allow better control over plasma density and energy distribution. This can lead to better control over etching or deposition rates, enabling manufacturers to fine-tune processes to meet specific requirements for different materials or applications.

Higher plasma density also improves process efficiency by increasing the ionization of gases, making it possible to achieve faster processing rates without compromising on precision. The ability to assist plasma breakdown with additional electrodes provides manufacturers with more flexibility in customizing the plasma characteristics for different applications. Different electrode configurations can be used to modulate the plasma's energy and density profile, allowing the chamber to be optimized for specific materials, feature sizes, or etching depths. This adaptability enhances the chamber's versatility for use in a broader range of semiconductor manufacturing processes.

Further, the magnets (e.g., the magnets 510, 520) produce a magnetic field that will confine and enhance plasma intensity by magnetize the plasma ions. This limits plasma interaction with the outer portions of the processing volume, e.g., the chamber walls, so as to allow high power application without increasing the risk of hardware damage. Magnetizing the plasma using the substrate processing chamber of the present disclosure also prolongs plasma decay by inhibiting electron diffusion, thus enhancing and expanding the process pulsing window. The addition of the magnets also increases the plasma etch rate. The magnets allow for further tuning of the plasma uniformity on the substrate surface, which is particularly favorable for edge uniformity tuning.

Incorporating electrodes near the chamber lid and ICP coils, along with magnets along the chamber liner, can significantly enhance plasma breakdown and control in the processing chamber 100. By combining these elements, a more efficient, stable, and controllable plasma environment can be created. Electrodes near the chamber lid and ICP coils create localized high-voltage regions, which accelerate free electrons and promote ionization. This leads to faster plasma breakdown at a lower voltage, reducing the overall power needed to ignite the plasma. The electrodes ensure strong electric fields near key regions (such as near the chamber lid), helping initiate the plasma more quickly and uniformly throughout the chamber. Magnets placed along the chamber liner create a magnetic field that interacts with the moving electrons in the plasma. This causes the electrons to follow helical paths, increasing their path length within the chamber. The longer path means that electrons experience more collisions with gas molecules, resulting in enhanced ionization and aiding the plasma breakdown process. Magnetic fields help to trap high-energy electrons close to the chamber wall or within certain regions of the plasma, increasing plasma density and improving overall energy efficiency. The electrodes initiate the plasma by providing the initial ionization, while the magnets confine and guide electrons, improving the efficiency of the breakdown process and maintaining the plasma state.

This combination results in faster, more stable plasma formation and helps to reduce the breakdown voltage. The synergy between the electric fields from the electrodes and the magnetic fields from the magnets leads to a more controlled and sustained plasma. Electrodes provide a direct mechanism to control electric field distribution in the chamber, while magnets help to guide and shape the plasma. By carefully positioning both electrodes and magnets, the plasma can be made more uniform across the substrate surface. This uniformity is beneficial for achieving consistent etching or deposition rates across large substrates, reducing the likelihood of defects caused by uneven plasma exposure. The combined effect of the electrodes and the magnets leads to more efficient use of the plasma across the entire processing area, ensuring high yield.

FIG. 5 illustrates a schematic, cross-sectional view of a portion 500 of a substrate processing chamber, according to certain embodiments. The portion 500 includes a processing region 502. The processing region 502 is bound by a chamber liner 504 having an upper portion 506 and a lower portion 508. An upper magnet 510 having an upper magnet shield 512 is disposed on the upper portion 506 of the chamber liner 504 and within the processing region 502, e.g., not outside of the processing chamber. The upper magnet 510 is annular and is disposed along a perimeter of the chamber liner 504, e.g., is concentric with the chamber liner 504, and encircles the processing region 502. A lower magnet 520 having a lower magnet shield 522 is disposed on the lower portion 508 of the chamber liner 504 and within the processing region 502, e.g., not outside of the processing chamber. Similar to the upper magnet 510, the lower magnet 520 is annular and encircles the processing region 502 along the chamber liner 504.

The upper magnet shield 512 and the lower magnet shield 522 allow magnetic fields generated by the upper magnet 510 and the lower magnet 520 to permeate into the processing region 502 while covering the upper magnet 510 and the lower magnet 520, respectively, to protect the magnets from the plasma generated within the processing region 502. As such the upper magnet shield 512 and the lower magnet shield 522 are made of plasma-resistant materials. For example, the upper magnet shield 512 and the lower magnet shield 522 may be made of plasma resistant materials, such as silicon carbide, anodized aluminum, chrome, or a combination thereof. Each of the upper magnet 510 and the lower magnet 520 may include an electromagnetic coil, the electromagnetic coil having about 20 to about 200 turns, such as about 50 to about 150 turns. The upper magnet 510 and the lower magnet 520 generate a uniform magnetic field inside the processing region 502 during operation, enhancing the plasma generated by the induction coils, e.g., the induction coils 214.

A substrate support assembly 530 includes a substrate support magnet 532 disposed on an outer surface of a cathode liner 534 and inside the processing region 502. A substrate support magnet shield 536 is disposed outside of the substrate support magnet 532, enclosing the substrate support magnet 532 between the substrate support magnet shield 536 and the cathode liner 534. As with the upper magnet shield 512 and the lower magnet shield 522, the substrate support magnet shield 536 allows magnetic fields to permeate into the processing region 502 and is configured to protect the substrate support magnet 532 from the plasma generated in the processing region 502. This allows the substrate support magnet 532 to generate a magnetic field that will influence, e.g., energize, the plasma in the processing region 502 effectively as the substrate support magnet 532 is located within the processing region 502 itself.

The metal ring 410 includes one or more electrodes incorporated therein. In one example, the metal ring 410 includes the segmented electrodes 222. In another example, the metal ring 410 includes the single electrode 322. The metal ring 410 with the electrodes incorporated therein is positioned directly above the top portion of the chamber liner 504. The electrodes may be vertically aligned with the upper magnet 510 and the lower magnet 520. The electrodes (segmented electrodes 222 or single electrode 322) cooperate with the upper magnet 510 and the lower magnet 520 to significantly enhance plasma breakdown and control in the processing chamber 100. This combination results in faster, more stable plasma formation and helps to reduce the breakdown voltage. The synergy between the electric fields from the electrodes and the magnetic fields from the magnets leads to a more controlled and sustained plasma. As such, the upper magnet 510 and the lower magnet 520 placed below the dielectric material 435 and below the electrodes (222, 322) are used to create a magnetic field that confines the plasma. The magnetic field helps enhance electron confinement and improve plasma density. The electrodes (222, 322) places above the upper magnet 510 and the lower magnet 520 and below the dielectric material 435 create an electric field needed to ionize the gas and generate the plasma. The combined effect of the electrodes and the magnets leads to more efficient use of the plasma across the entire processing area, ensuring high yield. The combination of the metal lid support ring 220, the dielectric material 435, the electrodes (222, 322), and the magnets (510, 520) ensures confinement of the plasma 110 within a desired area and ensures that the plasma 110 remains evenly distributed across the substrate 154. By controlling both the electric and magnetic fields, the system achieves consistent plasma characteristics, improving process outcomes.

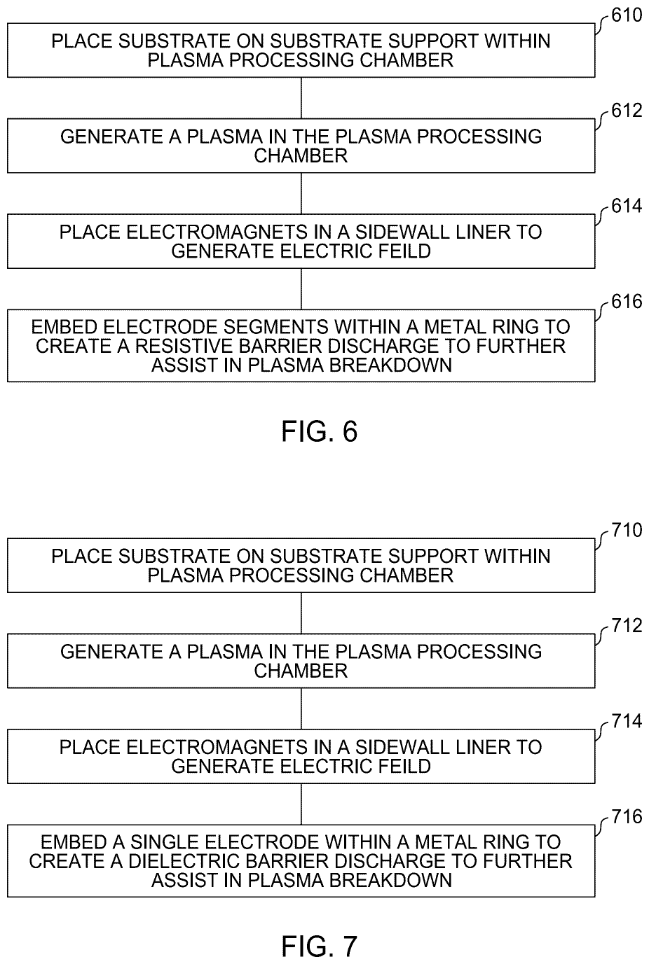

FIG. 6 is a flowchart of using segmented electrodes adjacent a metal lid support ring for supporting magnetically enhanced resistive barrier discharge, according to certain embodiments.

At operation 610, the substrate is placed on a substrate support within the plasma processing chamber. For example, the substrate 154 may be positioned within the processing chamber 100 to form the one or more low-k films on the substrate 154.

At operation 612, a plasma is generated in the plasma processing chamber. For example, one or more process gases may be introduced by the gas supply source 111 to the processing chamber 100 to deposit a low-k film on the substrate. The process gases may include at least one precursor gas, ionizable gas and carrier gas, and one or more of the processing gases may be ionized to form a plasma. The electrode 122 may be driven with an RF signal by the power source 136 to ionize the processing gas or gases into forming and maintaining the plasma 110. Further, the precursor gas may be utilized to form a film on the substrate 154 in the presence of the plasma 110.

At operation 614, electromagnets are placed in a sidewall liner to generate electric field. For example, the electromagnet of the plasma confinement assembly 150 disposed in the first cavity of the chamber wall liner 180 may be energized by the first power source 128. In another example, the second electromagnet of the plasma confinement assembly 150 disposed in the second cavity of the chamber wall liner 180 may be energized by the first power source 128.

At operation 616, electrode segments are integrated within a metal ring to create a resistive barrier discharge to further assist in plasma breakdown. In one example, segmented electrodes are placed within a metal ring and RBD takes place to create a high voltage near a chamber lid of a processing chamber, near the inductive coils (or ICP coils), such that the voltage stacks on to the ICP's to assist with plasma breakdown.

FIG. 7 is a flowchart of using a single electrode adjacent a metal lid support ring for supporting magnetically enhanced dielectric barrier discharge, according to certain embodiments.

At operation 710, the substrate is placed on a substrate support within the plasma processing chamber. For example, the substrate 154 may be positioned within the processing chamber 100 to form the one or more low-k films on the substrate 154.

At operation 712, a plasma is generated in the plasma processing chamber. For example, one or more process gases may be introduced by the gas supply source 111 to the processing chamber 100 to deposit a low-k film on the substrate. The process gases may include at least one precursor gas, ionizable gas and carrier gas, and one or more of the processing gases may be ionized to form a plasma. The electrode 122 may be driven with an RF signal by the power source 136 to ionize the processing gas or gases into forming and maintaining the plasma 110.

At operation 714, electromagnets are placed in a sidewall liner to generate electric field. For example, the first electromagnet of the plasma confinement assembly 150 disposed in the first cavity of the chamber wall liner 180 may be energized by the first power source 128.

At operation 716, a single electrode is integrated within a metal ring to create a dielectric barrier discharge to further assist in plasma breakdown. In another example, a single electrode is placed within a metal ring and DBD takes place to create a high voltage near a chamber lid of a processing chamber, near the inductive coils (or ICP coils), such that the voltage stacks on to the ICP's to assist with plasma breakdown.

In conclusion, segmented electrodes are placed within a metal ring and RBD takes place to create a high voltage near a chamber lid of a processing chamber, near the inductive coils (or ICP coils), such that the voltage stacks on to the ICP's to assist with plasma breakdown. In another example, a single electrode is placed within a metal ring and DBD takes place to create a high voltage near a chamber lid of a processing chamber, near the inductive coils (or ICP coils), such that the voltage stacks on to the ICP's to assist with plasma breakdown. Breaking down plasma can help achieve uniform plasma distribution across the surface of the material being processed. This results in consistent material characteristics, which is valuable for producing high-quality semiconductor devices or thin films. The example embodiments break down plasma by incorporating either segmented electrodes or a single electrode in a metal ring of the processing chamber to create a high voltage near the chamber lid and near the ICP coils, using either RBD or DBD. The combined effect of the electrodes and the magnets leads to more efficient use of the plasma across the entire processing area, ensuring high yield. The combination of a metal lid support ring, a dielectric material, the electrodes, and the magnets ensure confinement of the plasma within a desired area and ensure that the plasma remains evenly distributed across a substrate. By controlling both the electric and magnetic fields, the system achieves consistent plasma characteristics, improving process outcomes.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
a chamber body;
a substrate support assembly disposed within the chamber body;
a lid assembly enclosing a processing region within the chamber body, the lid assembly comprising an inductive coil configured to generate a plasma within the processing region of the chamber body;
at least one magnet coupled to a magnet power source; and
a plurality of electrodes positioned in a radial pattern within a metal ring, wherein the plurality of electrodes are placed above the at least one magnet.

2. The substrate processing chamber of claim 1, wherein the plurality of electrodes are equally spaced apart from each other.

3. The substrate processing chamber of claim 1, wherein the plurality of electrodes are powered by a power supply coupled to a low pass filter (LPF).

4. The substrate processing chamber of claim 1, wherein resistive barrier discharge (RBD) takes place to generate a high voltage near the lid assembly and near the inductive coil, such that voltage stacks onto the inductive coil to assist with plasma breakdown.

5. The substrate processing chamber of claim 1, wherein the plurality of electrodes are placed below a metal lid support ring.

6. The substrate processing chamber of claim 5, wherein the metal lid support ring, the plurality of electrodes, and the at least one magnet collectively ensure confinement of the plasma within a desired area and that the plasma remains evenly distributed across a substrate placed on the substrate support assembly.

7. The substrate processing chamber of claim 1, wherein the plurality of electrodes are vertically aligned with the at least one magnet.

8. The substrate processing chamber of claim 1, wherein the metal ring includes a plurality of gas nozzles.

9. A substrate processing chamber, comprising:
a chamber body;
a substrate support assembly disposed within the chamber body;
a lid assembly enclosing a processing region within the chamber body, the lid assembly comprising an inductive coil configured to generate a plasma within the processing region of the chamber body;
at least one magnet coupled to a magnet power source; and
a single electrode positioned within a metal ring to circumferentially extend along a perimeter of the chamber body, wherein the single electrode is placed above the at least one magnet.

10. The substrate processing chamber of claim 9, wherein the single electrode is powered by a power supply coupled to a pair of variable capacitors.

11. The substrate processing chamber of claim 9, wherein dielectric barrier discharge (DBD) takes place to generate a high voltage near the lid assembly and near the inductive coil, such that voltage stacks onto the inductive coil to assist with plasma breakdown.

12. The substrate processing chamber of claim 9, wherein the single electrode is placed below a metal lid support ring.

13. The substrate processing chamber of claim 12, wherein the metal lid support ring, the single electrode, and the at least one magnet collectively ensure confinement of the plasma within a desired area and that the plasma remains evenly distributed across a substrate placed on the substrate support assembly.

14. The substrate processing chamber of claim 9, wherein the single electrode is vertically aligned with the at least one magnet.

15. The substrate processing chamber of claim 9, wherein the metal ring includes a plurality of gas nozzles.

16. A method, comprising:
forming a substrate support assembly within a chamber body;
disposing a lid assembly enclosing a processing region within the chamber body, the lid assembly comprising an inductive coil configured to generate a plasma within the processing region of the chamber body;
placing at least one magnet adjacent the chamber body; and
positioning at least one electrode within a metal ring to circumferentially extend along a perimeter of the chamber body.

17. The method of claim 16, wherein resistive barrier discharge (RBD) takes place to generate a high voltage near the lid assembly and near the inductive coil, such that voltage stacks onto the inductive coil to assist with plasma breakdown.

18. The method of claim 16, wherein dielectric barrier discharge (DBD) takes place to generate a high voltage near the lid assembly and near the inductive coil, such that voltage stacks onto the inductive coil to assist with plasma breakdown.

19. The method of claim 16, wherein the at least one electrode is placed below a metal lid support ring and above the at least one magnet.

20. The method of claim 19, wherein the metal lid support ring, the at least one electrode, and the at least one magnet collectively ensure confinement of the plasma within a desired area and that the plasma remains evenly distributed across a substrate placed on the substrate support assembly.
